(19) United States
(12) Patent Application Publication
(10) Pub. No.: US 2025/0267945 A1
(43) Pub. Date: Aug. 21, 2025

(54) DISPLAY DEVICE

(71) Applicant: LG Display Co., Ltd., Seoul (KR)

(72) Inventors: Yeonjun OH, Incheon (KR); SungJoon MIN, Goyang-si (KR); Dojoong KIM, Seoul (KR); JunHyuk SONG, Seoul (KR); Taehyun KIM, Uijeongbu-si (KR)

(21) Appl. No.: 18/928,618

(22) Filed: Oct. 28, 2024

(30) Foreign Application Priority Data
Feb. 20, 2024 (KR) 10-2024-0024345

(51) Int. Cl. H01L 27/12; H01L 25/16

(52) U.S. Cl. CPC H10D 86/60; H01L 25/167; H10D 86/441; H10D 86/451

(57) ABSTRACT

According to an aspect of the present disclosure, a display device includes a lower substrate which includes a plurality of rigid areas disposed to be spaced apart from each other and a malleable area enclosing the plurality of rigid areas; a plurality of first plate patterns disposed in the plurality of rigid areas of the lower substrate; and a plurality of sub pixels which are disposed on the plurality of first plate patterns and each include a connection electrode, a conductive adhesive layer on the connection electrode, and a light emitting diode on the conductive adhesive layer, wherein some of the plurality of sub pixels include a repair electrode which is disposed between the connection electrode and the conductive adhesive layer and is formed of an iodine pattern including an iodine component and a metal pattern.

### CROSS-REFERENCE TO RELATED APPLICATIONS

This application claims the priority of Korean Patent Application No. 10-2024-0024345 filed on Feb. 20, 2024, in the Korean Intellectual Property Office, the disclosure of which is incorporated herein by reference.

### BACKGROUND

### Technical Field

The present disclosure relates to a display device, and more particularly to a stretchable display device which can be stretched.

### Description of the Related Art

As display devices which are used for a monitor of a computer, a television, or a cellular phone, there are an organic light emitting display device (OLED) which is a self-emitting device and a liquid crystal display device (LCD) which includes a separate light source.

An applicable range of the display device is diversified to include personal digital assistants as well as monitors of computers and televisions, and a display device with a large display area and a reduced volume and weight is being studied.

Recently, a display device which is manufactured by forming a display unit, a wiring line, and the like on a flexible substrate such as plastic which is a flexible material so as to be stretchable in a specific direction and changed in various forms is getting attention as a next generation display device.

### BRIEF SUMMARY

The present disclosure provides a display device which repairs a defective light emitting diode.

The present disclosure provides a display device which removes a defective light emitting diode.

The present disclosure provides a display device which avoids or reduces a damage of a connection electrode when the defective light emitting diode is removed.

The present disclosure provides a display device which simply repairs the defective light emitting diode using a solution.

The present disclosure provides a display device with an improved reliability.

Technical features of the present disclosure are not limited to those above-mentioned, and other technical features and characteristics, which are not mentioned above, can be clearly understood by those skilled in the art from the following descriptions.

According to an aspect of the present disclosure, a display device includes a lower substrate which includes a plurality of rigid areas disposed to be spaced apart from each other and a malleable area enclosing the plurality of rigid areas; a plurality of first plate patterns disposed in the plurality of rigid areas of the lower substrate; and a plurality of sub pixels which are disposed on the plurality of first plate patterns and each include a connection electrode, a conductive adhesive layer on the connection electrode, and a light emitting diode on the conductive adhesive layer, wherein some of the plurality of sub pixels include a repair electrode which is disposed between the connection electrode and the conductive adhesive layer and is formed of an iodine pattern including an iodine component and a metal pattern. Accordingly, during the repair process of a sub pixel from which a defect is detected, an iodine pattern of the repair electrode is solutionized to remove the metal pattern to easily remove the conductive adhesive layer and the defective light emitting diode.

Other detailed matters of the exemplary embodiments are included in the detailed description and the drawings.

According to the present disclosure, the display device may repair the defective light emitting diode.

According to the present disclosure, the display device may reduce defects in a sub-pixel by removing the defective light emitting diode and transferring a normal light emitting diode.

According to the present disclosure, when the defective light emitting diode is removed, the damage of the connection electrode may be reduced.

According to the present disclosure, the display device may simply repair the defective light emitting diode using a solution.

According to the present disclosure, the display device easily repairs the defective sub pixel to improve the reliability.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a plan view of a display device according to an exemplary embodiment of the present disclosure;

FIG. 2 is an enlarged plan view of an active area of a display device according to an exemplary embodiment of the present disclosure;

FIG. 3 is a cross-sectional view of a sub pixel of a display device according to an exemplary embodiment of the present disclosure;

FIGS. 4A to 4I are exemplary plan views of a repair electrode of a display device according to an exemplary embodiment of the present disclosure; and

FIGS. 5 to 7 are process diagrams for explaining a repairing method of a display device according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an exemplary embodiments of the present disclosure will be described in detail with reference to accompanying drawings.

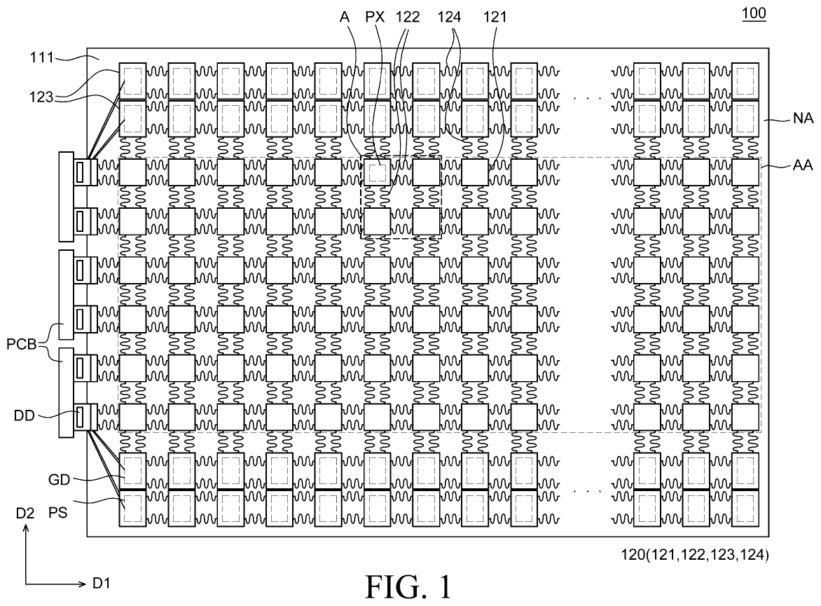

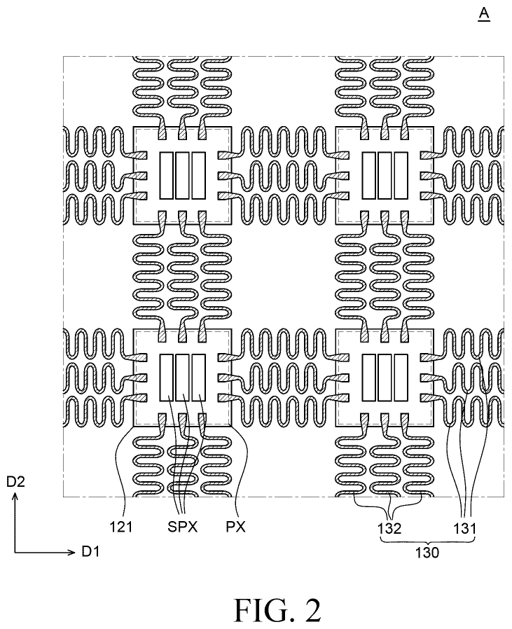

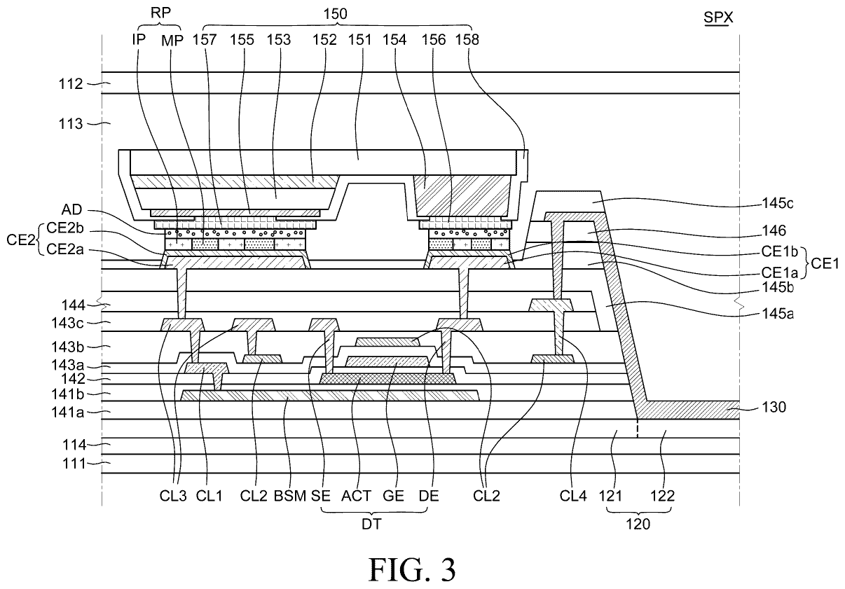

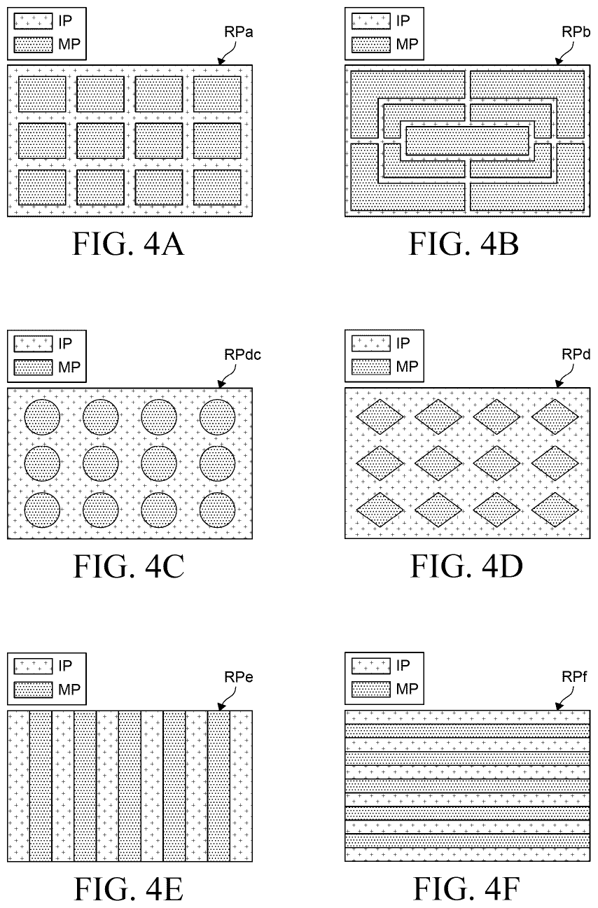

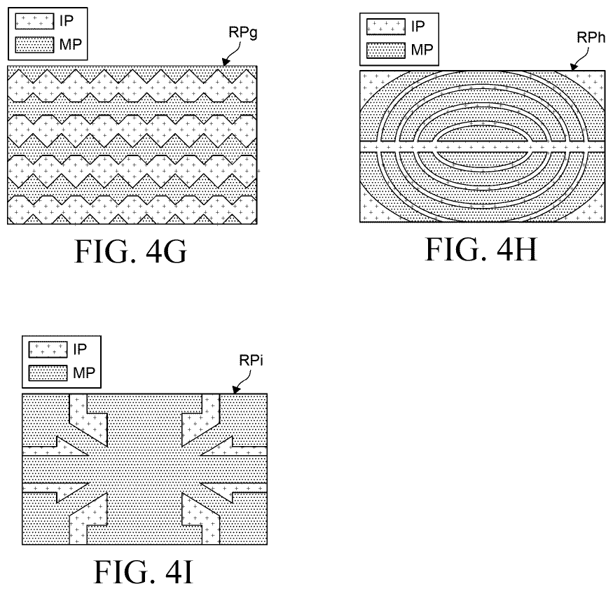

FIG. 1 is a plan view of a display device according to an exemplary embodiment of the present disclosure. FIG. 2 is an enlarged plan view of an active area of a display device according to an exemplary embodiment of the present disclosure. FIG. 3 is a cross-sectional view of a sub pixel of a display device according to an exemplary embodiment of the present disclosure. FIGS. 4A to 4I are exemplary plan views of a repair electrode of a display device according to an exemplary embodiment of the present disclosure.

First, a display device 100 according to an exemplary embodiment of the present disclosure is a display device 100 which is capable of displaying images even in a bent or extended state and may also be referred to as a stretchable display device 100, a flexible display device 100, and an extendable display device 100. As compared with the general display devices of the related art, the display device 100 may have not only a high flexibility, but also stretchability. Therefore, the user may bend or extend a display device 100 and a shape of a display device 100 may be freely changed in accordance with manipulation of a user. For example, when the user pulls the display device 100 by holding ends of the display device 100, the display device 100 may be extended to the pulling direction of the user. Alternatively, when the user disposes the display device 100 on an outer surface which is not flat, the display device 100 may be disposed to be bent in accordance with the shape of the outer surface. Further, when a force applied by the user is removed, the display device 100 may return to its original shape.

Referring to FIGS. 1 to 3, the lower substrate 111 is a substrate which supports and protects several components of the display device 100. The lower substrate 111 may support a pattern layer 120 on which the pixels PX, the gate driver GD, and the power supply PS are formed.

An upper substrate 112 is a substrate which covers and protects several components of the display device 100. The upper substrate 112 may cover the pixels PX, the gate driver GD, and the power supply PS.

The lower substrate 111 and the upper substrate 112 which are flexible substrates may be configured by an insulating material which is bendable or extendable. For example, the lower substrate 111 and the upper substrate 112 may be formed of a silicon rubber such as polydimethylsiloxane (PDMS) or an elastomer such as polyurethane (PU) and polytetrafluoroethylene (PTFE) and thus have a flexibility. Further, the materials of the lower substrate 111 and the upper substrate 112 may be the same, but are not limited thereto and may vary.

The lower substrate 111 and the upper substrate 112 are flexible substrates so as to be reversibly expandable and contractible. Accordingly, the lower substrate 111 may be referred to as a lower stretchable substrate, a lower stretching substrate, a lower extending substrate, a lower ductile substrate, a lower flexible substrate, a first stretchable substrate, a first stretching substrate, a first extending substrate, a first ductile substrate, a first flexible substrate, or the like. The upper substrate 112 may be referred to as an upper stretchable substrate, an upper stretching substrate, an upper extending substrate, an upper ductile substrate, an upper flexible substrate, a second stretchable substrate, a second stretching substrate, a second extending substrate, a second ductile substrate, a second flexible substrate, or the like.

Moduli of elasticity of the lower substrate 111 and the upper substrate 112 may be several MPa to several hundreds of MPa. Further, a ductile breaking rate of the lower substrate 111 and the upper substrate 112 may be 100% or higher. Here, the ductile breaking rate refers to a stretching rate at a timing when an object to be stretched is broken or cracked. A thickness of the lower substrate 111 may be 10 um to 1 mm, but is not limited thereto.

The lower substrate 111 includes an active area AA and a non-active area NA enclosing the active area AA. However, the active area AA and the non-active area NA are not mentioned to be limited only to the lower substrate 111, but mentioned for the entire display device 100.

The active area AA is an area in which images are displayed in the display device 100 and a plurality of pixels PX is disposed in the active area AA. Each pixel PX may include a display element and various driving elements for driving the display element. Various driving elements may refer to at least one thin film transistor (TFT) and a capacitor, but are not limited thereto. The plurality of pixels PX may be connected to various wiring lines to be driven, respectively. For example, each of the plurality of pixels PX may be connected to various wiring lines, such as a scan line, a data line, a high potential voltage line, a low potential voltage line, a reference voltage line, and an initialization voltage line.

The non-active area NA is an area where no image is displayed. The non-active area NA may be an area adjacent to the active area AA. The non-active area NA is adjacent to the active area AA to enclose the active area AA, but is not limited thereto. The non-active area NA may correspond to an area excluding the active area AA from the lower substrate 111 and may be modified and separated in various forms. In the non-active area NA, various components for driving a plurality of pixels PX disposed in the active area AA, such as a gate driver GD and a power supply PS, may be disposed. In the non-active area NA, a plurality of pads connected to the data driver DD and the printed circuit board PCB may be disposed and each pad may be connected to each of the plurality of pixels PX of the active area AA.

A filling layer 113 is disposed between the lower substrate 111 and the upper substrate 112. The filling layer 113 may be fully filled in an empty space between the lower substrate 111 and the upper substrate 112. For example, the filling layer 113 may be configured by a curable adhesive. Specifically, the material which configures the filling layer 113 is coated on the entire surface of the lower substrate 111 and then is cured so that the filling layer 113 may be disposed between the components disposed on the upper substrate 112 and the lower substrate 111. For example, the filling layer 113 may be an optically clear adhesive (OCA) and may be configured by an acrylic adhesive, a silicon-based adhesive, and a urethane-based adhesive.

The pattern layer 120 is disposed on the lower substrate 111. The pattern layer 120 may include a plurality of first plate patterns 121 and a plurality of first line patterns 122 disposed in the active area AA and a plurality of second plate patterns 123 and a plurality of second line patterns 124 disposed in the non-active area NA.

A plurality of plate patterns is disposed in the active area AA and the non-active area NA. The plurality of plate patterns includes a plurality of first plate patterns 121 and a plurality of second plate patterns 123. The plurality of first plate patterns 121 is disposed in the active area AA of the lower substrate 111 and the plurality of second plate patterns 123 is disposed in the non-active area NA of the lower substrate 111. On the plurality of first plate patterns 121, a plurality of pixels PX is formed and on the plurality of second plate patterns 123, a gate driver GD and a power supply PS may be formed.

The plurality of first plate patterns 121 and the plurality of second plate patterns 123 may be disposed in the form of separate islands. The plurality of first plate patterns 121 and the plurality of second plate patterns 123 may be individually separated. Therefore, the plurality of first plate patterns 121 and the plurality of second plate patterns 123 may be referred to as first island patterns and second island patterns or first individual patterns and second individual patterns.

A size of each of the plurality of second plate patterns 123 may be larger than a size of each of the plurality of first plate patterns 121. In each of the plurality of second plate patterns 123, one stage of the gate driver GD may be disposed. Therefore, an area occupied by various circuit configurations which configure one stage of the gate driver GD may be relatively larger than an area occupied by one pixel PX so that a size of each of the plurality of second plate patterns 123 may be larger than a size of each of the plurality of first plate patterns 121.

In the meantime, even though it is illustrated in FIG. 1 that the plurality of second plate patterns 123 is disposed in the non-active area NA on both sides of the active area AA in the second direction D2, this is illustrative so that the plurality of second plate patterns 123 may be disposed in an arbitrary area of the non-active area NA. Further, even though it is illustrated that the plurality of first plate patterns 121 and the plurality of second plate patterns 123 each have a rectangular shape, the present disclosure is not limited thereto, and the shapes of the plurality of first plate patterns 121 and the plurality of second plate patterns 123 may vary in various forms.

Referring to FIGS. 1 and 2, the plurality of line patterns is disposed in the active area AA and the non-active area NA. The plurality of line patterns includes a plurality of first line patterns 122 and a plurality of second line patterns 124.

The plurality of first line patterns 122 is disposed in the active area AA. The plurality of first line patterns 122 is patterns which connect first plate patterns 121 which are adjacent to each other and may be referred to as internal connection patterns. That is, the plurality of first line patterns 122 may be disposed between the plurality of first plate patterns 121.

The plurality of second line patterns 124 of the pattern layer 120 is disposed in the non-active area NA. The plurality of second line patterns 124 connects the first plate pattern 121 and the second plate pattern 123 which are adjacent to each other or connects a plurality of adjacent second plate patterns 123 and may be referred to as external connection patterns. The plurality of second line patterns 124 may be disposed between the first plate pattern 121 and the second plate pattern 123 which are adjacent to each other and between the plurality of second plate patterns 123 which is adjacent to each other.

The plurality of first line patterns 122 and the plurality of second line patterns 124 may each have a wavy shape. For example, the plurality of first line patterns 122 and the plurality of second line patterns 124 may each have a sinusoidal shape. However, the shapes of the plurality of first line patterns 122 and the plurality of second line patterns 124 are not limited thereto. For example, the plurality of first line patterns 122 and the plurality of second line patterns 124 may each extend in a zigzag pattern. Further, the plurality of first line patterns 122 and the plurality of second line patterns 124 may have various shapes such as a shape in which a plurality of rhombic substrates are connected at their vertexes to be extended or a shape in which semi-circular and quadrant-shaped substrates are connected to each other. Further, the number and the shape of the plurality of first line patterns 122 and the plurality of second line patterns 124 illustrated in FIG. 1 are illustrative and may be changed in various forms depending on the design.

In the meantime, the plurality of first plate patterns 121, the plurality of first line patterns 122, the plurality of second plate patterns 123, and the plurality of second line patterns 124 are rigid patterns. That is, the plurality of first plate patterns 121, the plurality of first line patterns 122, the plurality of second plate patterns 123, and the plurality of second line patterns 124 may be more rigid than the lower substrate 111 and the upper substrate 112.

The plurality of first plate patterns 121, the plurality of first line patterns 122, the plurality of second plate patterns 123, and the plurality of second line patterns 124 which are rigid substrates may be formed of a plastic material having a lower flexibility than the lower substrate 111 and the upper substrate 112. For example, the plurality of first plate patterns 121, the plurality of first line patterns 122, the plurality of second plate patterns 123, and the plurality of second line patterns 124 may be formed of at least one material of polyimide (PI), polyacrylate, and polyacetate. At this time, when the plurality of first plate patterns 121, the plurality of first line patterns 122, the plurality of second plate patterns 123, and the plurality of second line patterns 124 are formed of the same material, the plurality of first plate patterns 121, the plurality of first line patterns 122, the plurality of second plate patterns 123, and the plurality of second line patterns 124 may be integrally formed. However, the plurality of first plate patterns 121, the plurality of first line patterns 122, the plurality of second plate patterns 123, and the plurality of second line patterns 124 may be formed of different materials, but are not limited thereto.

Moduli of elasticity of the plurality of first plate patterns 121, the plurality of first line patterns 122, the plurality of second plate patterns 123, and the plurality of second line patterns 124 may be higher than a modulus of elasticity of the lower substrate 111. The modulus of elasticity is a parameter representing a rate of deformation against the stress applied to the substrate and the higher the modulus of elasticity, the higher the hardness. Therefore, the plurality of first plate patterns 121, the plurality of first line patterns 122, the plurality of second plate patterns 123, and the plurality of second line patterns 124 may be referred to as a plurality of first rigid patterns, a plurality of second rigid patterns, a plurality of third rigid patterns, and a plurality of fourth rigid patterns, respectively. Moduli of elasticity of the plurality of first plate patterns 121, the plurality of first line patterns 122, the plurality of second plate patterns 123, and the plurality of second line patterns 124 may be 1000 times higher than the moduli of elasticity of the lower substrate 111 and the upper substrate 112, but they are not limited thereto.

In the meantime, in some exemplary embodiments, the lower substrate 111 may include a plurality of rigid areas and malleable areas. The plurality of rigid areas may be disposed to be spaced apart from each other. The plurality of rigid areas may be areas of the lower substrate 111 overlapping the plurality of first plate patterns 121 and the plurality of second plate patterns 123. The plurality of rigid areas may be areas in which the plurality of first plate patterns 121 and the plurality of second plate patterns 123 are disposed to have a rigid characteristic. The malleable area may be an area which encloses each of the plurality of rigid areas. The malleable area may be an area which does not overlap the plurality of first plate patterns 121 and the plurality of second plate patterns 123. The malleable area is an area between the plurality of first plate patterns 121 and the plurality of second plate patterns 123 and may include an area in which the plurality of first line patterns 122 and the plurality of second line patterns 124 are disposed. Further, the malleable area may include an area in which the pattern layer 120 is not disposed. The malleable area may be an area in which the plurality of first plate patterns 121 and the plurality of second plate patterns 123 are not disposed to be flexibly deformable. In the plurality of rigid areas, the plurality of first plate patterns 121 and the plurality of second plate patterns 123 are disposed and in the malleable area, the plurality of first plate patterns 121 and the plurality of second plate patterns 123 are not disposed so that the plurality of rigid areas may be more rigid than the malleable area. At this time, the malleable area and the plurality of rigid areas are not mentioned to be limited only to the lower substrate 111, but mentioned for the entire display device 100.

In the meantime, in some exemplary embodiments, the lower substrate 111 may include a plurality of first lower patterns and a second lower pattern. The plurality of first lower patterns may be an area of the lower substrate 111 overlapping the plurality of first plate patterns 121 and the plurality of second plate patterns 123. The second lower pattern may be a remaining area which does not overlap the plurality of first plate patterns 121 and the plurality of second plate patterns 123.

Further, the upper substrate 112 may include a plurality of first upper patterns and a second upper pattern. The plurality of first upper patterns may be an area of the upper substrate 112 overlapping the plurality of the first plate patterns 121 and the plurality of second plate patterns 123, but the second upper pattern may be a remaining area which does not overlap the plurality of the first plate patterns 121 and the plurality of second plate patterns 123.

At this time, moduli of elasticity of the plurality of first lower patterns and the first upper pattern may be higher than moduli of elasticity of the second lower pattern and the second upper pattern. For example, the plurality of first lower patterns and the first upper pattern may be formed of the same material as the plurality of first plate patterns 121 and the plurality of second plate patterns 123. The second lower pattern and the second upper pattern may be formed of a material having a modulus of elasticity lower than those of the plurality of first plate patterns 121 and the plurality of second plate patterns 123.

For example, the first lower pattern and the first upper pattern may be formed of polyimide (PI), polyacrylate, or polyacetate. Further, the second lower pattern and the second upper pattern may be formed of silicon rubber such as polydimethylsiloxane (PDMS) or elastomer such as polyurethane (PU) or polytetrafluoroethylene.

The gate driver GD may be mounted on the plurality of second plate patterns 123. The gate driver GD may be formed on the plurality of second plate patterns 123 in a gate in panel (GIP) manner when various elements on the plurality of first plate patterns 121 are manufactured. Therefore, various circuit configurations which configure the gate driver GD, such as transistors, capacitors, and wiring lines, may be disposed on the plurality of second plate patterns 123. One stage which is a circuit which configures the gate driver GD and includes transistors and capacitors may be disposed above each of the plurality of second plate patterns 123. However, the gate driver GD may be mounted in a chip on film (COF) manner, but is not limited thereto.

A power supply PS may be disposed on the plurality of second plate patterns 123. The power supply PS may be formed on the second plate pattern 123 adjacent to the gate driver GD. The power supply PS is a plurality of power blocks patterned when various components on the first plate pattern 121 is manufactured and may be formed on the second plate pattern 123. The power supply PS is electrically connected to the gate driver GD of the non-active area NA and the plurality of pixels PX of the active area AA to supply a driving voltage. Specifically, the power supply PS may be electrically connected to the gate driver GD formed on the second plate pattern 123 and the plurality of pixels PX formed on the first plate pattern 121 by means of the second line pattern 124 and the first line pattern 122. For example, the power supply PS may supply a gate driving voltage and a clock signal to the gate driver GD. The power supply PS may supply the power voltage to each of the plurality of pixels PX.

The printed circuit board PCB is connected to an edge of the lower substrate 111. The printed circuit board PCB is a component which transmits signals and voltages for driving the display element from the controller to the display element. Therefore, the printed circuit board PCB may also be referred to as a driving substrate. A controller, such as an IC chip or a circuit unit, may be mounted on the printed circuit board PCB. Further, on the printed circuit board PCB, a memory or a processor may also be mounted. The printed circuit board PCB provided in the display device 100 may include a stretching area and a non-stretching area to ensure stretchability. In the non-stretching area, an IC chip, a circuit unit, a memory, and a processor may be mounted and in the stretching area, wiring lines which are electrically connected to the IC chip, the circuit unit, the memory, and the processor may be disposed.

The data driver DD is a component which supplies a data voltage to the plurality of pixels PX disposed in the active area AA. The data driver DD may be configured as an IC chip so that it may also be referred to as a data integrated circuit D-IC. The data driver DD may be mounted in the non-stretching area of the printed circuit board PCB. That is, the data driver DD may be mounted on the printed circuit board PCB in the form of a chip on board (COB). However, even though in FIG. 1, it is illustrated that the data driver DD is mounted in a COB manner, the data driver DD may be mounted in a chip on film (COF), a chip on glass (COG), or a tape carrier package (TCP) manner, but it is not limited thereto.

Further, even though in FIG. 1, one data driver DD is disposed so as to correspond to each of a plurality of columns formed by the plurality of first plate patterns 121 disposed in the active area AA, it is not limited thereto. That is, one data driver DD may be disposed so as to correspond to a plurality of columns formed by the plurality of first plate patterns 121.

Referring to FIGS. 1 and 2, the plurality of first plate patterns 121 is disposed in the active area AA of the lower substrate 111. The plurality of first plate patterns 121 may be disposed to be spaced apart from each other. For example, the plurality of first plate patterns 121 is disposed in a plurality of rows and a plurality of columns to be disposed in a matrix. For example, the plurality of first plate patterns 121 may be disposed to be spaced apart from each other with a predetermined interval in the first direction D1. The plurality of first plate patterns 121 may be disposed to be spaced apart from each other with a predetermined interval in the second direction D2.

The plurality of first line patterns 122 may be disposed in the active area AA of the lower substrate 111. The plurality of first line patterns 122 is disposed in an area between the plurality of first plate patterns 121 to connect the plurality of first plate patterns 121. The plurality of first line patterns 122 extends in the first direction D1 or the second direction D2 and may connect the first plate patterns 121 which are adjacent to each other in the first direction D1 or the second direction D2. For example, some first line patterns extending in the first direction D1, among the plurality of first line patterns 122, may connect one pair of first plate patterns 121 which are adjacent to each other in the first direction D1. The remaining first line patterns 122 extending in the second direction D1, among the plurality of first line patterns 122, may connect one pair of first plate patterns 121 which are adjacent to each other in the second direction D2.

Next, a substrate adhesive layer 114 may be disposed between the pattern layer 120 and the lower substrate 111. The substrate adhesive layer 114 is a layer for bonding the lower substrate 111 and the pattern layer 120. When the display device 100 is formed, after sequentially forming configurations of the pattern layer 120 and the plurality of sub pixels SPX on a rigid substrate, the rigid substrate and the pattern layer 120 are separated and the lower substrate 111 may be attached below the pattern layer 120. At this time, in order to fix the pattern layer 120 and the lower substrate 111, the substrate adhesive layer 114 may be disposed between the pattern layer 120 and the lower substrate 111. For example, the substrate adhesive layer 114 may be an optically clear adhesive (OCA), but is not limited thereto.

A pixel PX including the plurality of sub pixels SPX which is an individual unit to emit light is disposed in the plurality of first plate patterns 121. The plurality of sub pixels SPX may form one pixel PX. N sub pixels SPX which form one pixel PX may be disposed in each of the plurality of first plate patterns 121.

In the meantime, even though in the drawings, it is illustrated that one pixel PX includes three sub pixels SPX, the plurality of sub pixels SPX may further include a white sub pixel depending on a design of the display device 100 and a number and a configuration of the plurality of sub pixels SPX which forms one pixel PX are not limited thereto.

Each of the plurality of sub pixels SPX includes a light emitting diode 150 which is a display element and a pixel circuit for driving the light emitting diode 150.

The light emitting diode 150 may be configured by any one of various elements depending on a type of the display device 100. For example, when the display device 100 is an organic light emitting display device, the light emitting diode 150 may be an organic light emitting diode and when the display device 100 is an inorganic light emitting display device, the light emitting diode 150 may be a light emitting diode LED or a micro LED. Hereinafter, it is assumed that the light emitting diode 150 is a micro LED, but it is not limited thereto.

The pixel circuit supplies the driving current to the light emitting diode 150 to allow the light emitting diode 150 to emit light. The pixel circuit may include a plurality of transistors and capacitors. For example, the pixel circuit may include a plurality of transistors, such as a driving transistor DT or a switching transistor and a capacitor which is connected to any one of the plurality of transistors.

Hereinafter, a plurality of sub pixels SPX will be described in more detail with reference to FIGS. 2 and 3.

Referring to FIGS. 2 and 3, a plurality of inorganic insulating layers is disposed on the plurality of first plate patterns 121. For example, the plurality of inorganic insulating layers may include a multi-buffer layer 141a, an active buffer layer 141b, a gate insulating layer 142, a first interlayer insulating layer 143a, a second interlayer insulating layer 143b, a third interlayer insulating layer 143c, and a passivation layer 144. However, in addition to the above-described inorganic insulating layers, another inorganic insulating layer may be additionally disposed or one or more of the above-described inorganic insulating layers may be omitted and a configuration of the plurality of inorganic insulating layers is not limited thereto.

First, the multi-buffer layer 141a is disposed on the plurality of first plate patterns 121 and the active buffer layer 141b is disposed on the multi-buffer layer 141a. The multi-buffer layer 141a and the active buffer layer 141b may reduce the permeation of moisture or impurities from the outside of the lower substrate 111 and the first plate pattern 121. The multi-buffer layer 141a and the active buffer layer 141b may protect various components of the display device 100 from the moisture and oxygen of the outside. The multi-buffer layer 141a and the active buffer layer 141b may be formed of an insulating material. For example, each of the multi-buffer layer 141a and the active buffer layer 141b may be configured by a single layer or a double layer of silicon nitride (SiNx), silicon oxide (SiOx), and silicon oxynitride (SiON), but is not limited thereto. However, the multi-buffer layer 141a and the active buffer layer 141b may be omitted depending on a structure or a characteristic of the display device 100.

In the meantime, the multi-buffer layer 141a and the active buffer layer 141b may be formed only above the plurality of first plate patterns 121 and the plurality of second plate patterns 123. The multi-buffer layer 141a and the active buffer layer 141b may overlap the area in which the first plate patterns 121 and the second plate patterns 123 are disposed. The multi-buffer layer 141a and the active buffer layer 141b may not be formed in an area between the plurality of first plate patterns 121, an area between the plurality of second plate patterns 123 and an area between the plurality of first plate patterns 121 and the plurality of second plate patterns 123. The multi-buffer layer 141a and the active buffer layer 141b which are formed of an inorganic material may be easily cracked to be damaged during a process of stretching the display device 100. Therefore, the multi-buffer layer 141a and the active buffer layer 141b are patterned to have a shape of the plurality of first plate patterns 121 and the plurality of second plate patterns 123 to be formed only above the plurality of first plate patterns 121 and the plurality of second plate patterns 123. Accordingly, in the display device 100 according to the exemplary embodiment of the present disclosure, the multi-buffer layer 141a and the active buffer layer 141b are formed only in an area overlapping the plurality of first plate patterns 121 and the plurality of second plate patterns 123 which are rigid patterns. Therefore, even though the display device 100 is bent or stretched to be deformed, the damage of the multi-buffer layer 141a and the active buffer layer 141b may be suppressed so that the damages of various components of the display device 100 may also be suppressed.

A light shielding layer BSM may be disposed between the multi-buffer layer 141a and the active buffer layer 141b. The light shielding layer BSM blocks light which is incident onto the active layer ACT of the driving transistor DT, below the lower substrate 111 and the first plate pattern 121. Light which is incident onto the active layer ACT of the driving transistor DT is blocked by the light shielding layer BSM to reduce a leakage current. For example, the light shielding layer BSM may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto.

A driving transistor DT is disposed on the active buffer layer 141b. The driving transistor DT includes an active layer ACT, a gate electrode GE, a source electrode SE, and a drain electrode DE.

First, the active layer ACT is disposed on the active buffer layer 141b. The active layer ACT may be formed of a semiconductor material, such as an oxide semiconductor, amorphous silicon, or polysilicon, but is not limited thereto.

A gate insulating layer 142 is disposed on the active layer ACT. The gate insulating layer 142 is an insulating layer which insulates the active layer ACT from the gate electrode GE. The gate insulating layer 142 may be configured by a single layer or a double layer of silicon oxide (SiOx) or silicon nitride (SiNx), but is not limited thereto.

The gate electrode GE is disposed on the gate insulating layer 142. The gate electrode GE may be configured by a single layer or a multi-layered structure of a conductive material, such as copper (Cu), aluminum (Al), molybdenum (Mo), nickel (Ni), titanium (Ti), gold (Au), chrome (Cr), or an alloy thereof, but is not limited thereto.

The first interlayer insulating layer 143a is disposed on the gate electrode GE and the second interlayer insulating layer 143b is disposed on the first interlayer insulating layer 143a. The first interlayer insulating layer 143a and the second interlayer insulating layer 143b are insulating layers which protect components therebelow. The first interlayer insulating layer 143a and the second interlayer insulating layer 143b may be configured by a single layer or a double layer of silicon oxide (SiOx) or silicon nitride (SiNx), but are not limited thereto.

The source electrode SE and the drain electrode DE are disposed on the second interlayer insulating layer 143b. The source electrode SE and the drain electrode DE may be electrically connected to the active layer ACT through a contact hole formed in the second interlayer insulating layer 143b, the first interlayer insulating layer 143a, and the gate insulating layer 142. The source electrode SE and the drain electrode DE may be configured by a single layer or a multi-layered structure of a conductive material, such as copper (Cu), aluminum (Al), molybdenum (Mo), nickel (Ni), titanium (Ti), chrome (Cr), or an alloy thereof, but are not limited thereto.

Next, a first conductive layer CL1 is disposed between the gate insulating layer 142 and the first interlayer insulating layer 143a. The first conductive layer CL1 is an electrode which applies a voltage to the light shielding layer BSM. The light shielding layer BSM is electrically connected to another configuration disposed on the first plate pattern 121 through a first conductive layer CL1 to be applied with a voltage. The light shielding layer BSM which is applied with a voltage by means of the first conductive layer CL1 does not operate as a floating gate, and a fluctuation of a threshold voltage of the driving transistor DT which is generated by the floated light shielding layer BSM may therefore be reduced. The first conductive layer CL1 may be formed of the same conductive material as the gate electrode GE and for example, may be configured by a single layer or a multi-layered structure of copper (Cu), aluminum (Al), molybdenum (Mo), nickel (Ni), titanium (Ti), gold (Au), chrome (Cr), or an alloy thereof, but is not limited thereto.

A plurality of second conductive layers CL2 is disposed between the first interlayer insulating layer 143a and the second interlayer insulating layer 143b. The plurality of second conductive layers CL2 may configure at least a part of the plurality of wiring lines which supplies various signals to the sub pixel SPX or a configuration of the pixel circuit. For example, one second conductive layer CL2, among the plurality of second conductive layers CL2, may overlap the gate electrode GE of the driving transistor DT to form a capacitor. As another example, the other second conductive layer CL2, among the plurality of second conductive layers CL2, may be electrically connected to a connection line 130 through a fourth conductive layer CL4 which serves as a pad. The plurality of second conductive layers CL2 may be configured by a single layer or a multi-layered structure of a conductive material, such as copper (Cu), aluminum (Al), molybdenum (Mo), nickel (Ni), titanium (Ti), gold (Au), chrome (Cr), or an alloy thereof, but is not limited thereto.

A plurality of third conductive layers CL3 is disposed between the second interlayer insulating layer 143b and the third interlayer insulating layer 143c. The plurality of third conductive layers CL3 may configure at least a part of the plurality of wiring lines which supplies various signals to the sub pixel SPX or a configuration of the pixel circuit. The plurality of third conductive layers CL3 connects wiring lines disposed on different layers and may serve as a part of the wiring line. For example, a part of the plurality of third conductive layers CL3 may be electrically connected to the first conductive layer CL1 or the second conductive layer CL2. The plurality of third conductive layers CL3 may be formed on the same layer with the same material as the source electrode SE and the drain electrode DE of the driving transistor DT. For example, the plurality of third conductive layers CL3 may be configured by a single layer or a multi-layered structure of a conductive material, such as copper (Cu), aluminum (Al), molybdenum (Mo), nickel (Ni), titanium (Ti), gold (Au), chrome (Cr), or an alloy thereof, but is not limited thereto.

The third interlayer insulating layer 143c is disposed on the plurality of third conductive layers CL3 and the driving transistor DT. The third interlayer insulating layer 143c is an insulating layer which protects a configuration below the third interlayer insulating layer 143c. The third interlayer insulating layer 143c may be configured by a single layer or a double layer of silicon oxide (SiOx) or silicon nitride (SiNx), but is not limited thereto.

One or more fourth conductive layers CL4 are disposed on the third interlayer insulating layer 143c. The fourth conductive layers CL4 may configure at least a part of the plurality of wiring lines which supplies various signals to the sub pixel SPX or a configuration of the pixel circuit. The fourth conductive layer CL4 connects wiring lines disposed on different layers and may serve as a part of the wiring line. For example, the fourth conductive layer CL4 may serve as a pad which electrically connects a configuration on the first plate pattern 121 and the connection line 130. The fourth conductive layer CL4 may be configured by a single layer or a multi-layered structure of a conductive material, such as copper (Cu), aluminum (Al), molybdenum (Mo), nickel (Ni), titanium (Ti), gold (Au), chrome (Cr), or an alloy thereof, but is not limited thereto.

A passivation layer 144 is disposed on the fourth conductive layer CL4 and the third interlayer insulating layer 143c. The passivation layer 144 is an insulating layer which protects components below the passivation layer 144. The passivation layer 144 may be configured by a single layer or a double layer of silicon oxide (SiOx) or silicon nitride (SiNx), but is not limited thereto.

The first planarization layer 145a is disposed on the passivation layer 144. The first planarization layer 145a may planarize an upper portion of the first plate pattern 121 on which a plurality of conductive layers, a driving transistor DT, and a plurality of wiring lines are disposed. The first planarization layer 145a may be configured by a single layer or a plurality of layers and may be formed of an organic material. For example, the first planarization layer 145a may be configured by a single layer or a double layer, and for example, may be formed of photoresist or an acrylic organic material, but is not limited thereto.

The first connection electrode CE1 and the second connection electrode CE2 are disposed on the first planarization layer 145a. The first connection electrode CE1 and the second connection electrode CE2 are electrodes for electrically connecting the light emitting diode 150 to the pixel circuit. For example, the first connection electrode CE1 may electrically connect the light emitting diode 150 and the driving transistor DT and the second connection electrode CE2 may electrically connect the light emitting diode 150 and a third conductive layer CL3 which serves as a power line. At this time, the third conductive layer CL3 which serves as a power line may also be connected to the first conductive layer CLI and the light shielding layer BSM and thus a power voltage may be applied to the light shielding layer BSM.

The first connection electrode CE1 includes a first metal layer CE1a and a first clad layer CE1b. The first metal layer CE1a is disposed on the first planarization layer 145a and the first clad layer CE1b is disposed on the first metal layer CE1a.

The first metal layer CE1a may be electrically connected to any one of the source electrode SE or the drain electrode DE of the driving transistor DT, through a contact hole formed in the first planarization layer 145a, the passivation layer 144, and the third interlayer insulating layer 143c. The first metal layer CE1a may be configured by a single layer or a multi-layered structure of a conductive material, such as copper (Cu), aluminum (Al), molybdenum (Mo), nickel (Ni), titanium (Ti), gold (Au), chrome (Cr), or an alloy thereof, but is not limited thereto.

The first clad layer CE1b is disposed so as to cover the first metal layer CE1a. The first clad layer CE1b may be disposed so as to cover a top surface and a side surface of the first metal layer CE1a disposed on the first planarization layer 145a. The first clad layer CE1b may protect the first metal layer CE1a from being damaged due to the iodine solution generated during a repair process. For example, the first clad layer CE1b may be formed of a transparent conductive material, such as indium tin oxide (ITO) or indium zinc oxide (IZO), but is not limited thereto.

The second connection electrode CE2 includes a second metal layer CE2a and a second clad layer CE2b. The second metal layer CE2a is disposed on the first planarization layer 145a and the second clad layer CE2b is disposed on the second metal layer CE2a.

The second metal layer CE2a may be electrically connected to the third conductive layer CL3 which serves as a power line through a contact hole formed in the first planarization layer 145a, the passivation layer 144, and the third interlayer insulating layer 143c. The second metal layer CE2a may be configured by a single layer or a multi-layered structure of a conductive material, such as copper (Cu), aluminum (Al), molybdenum (Mo), nickel (Ni), titanium (Ti), gold (Au), chrome (Cr), or an alloy thereof, but is not limited thereto.

The second clad layer CE2b is disposed so as to cover the second metal layer CE2a. The second clad layer CE2b may be disposed so as to cover a top surface and a side surface of the second metal layer CE2a disposed on the second planarization layer 145b. The second clad layer CE2b may protect the second metal layer CE2a from being damaged due to the iodine solution generated during a repair process. For example, the second clad layer CE2b may be formed of a transparent conductive material, such as indium tin oxide (ITO) or indium zinc oxide (IZO), but is not limited thereto.

The second planarization layer 145b is disposed on the first connection electrode CE1, the second connection electrode CE2, and the first planarization layer 145a. The second planarization layer 145b may be disposed so as to enclose side surfaces of the first connection electrode CE1 and the second connection electrode CE2. The second planarization layer 145b may cover at least a part of the side surface of the first connection electrode CE1 and at least a part of the side surface of the second connection electrode CE2. The second planarization layer 145b may cover a top surface of the first planarization layer 145a. The second planarization layer 145b may be configured by a single layer or a plurality of layers and may be formed of an organic material. For example, the second planarization layer 145b may be configured by a single layer or a double layer, and for example, may be formed of photoresist or an acrylic organic material, but is not limited thereto.

In the meantime, a thickness of a part of the second planarization layer 145b corresponding to a boundary between the plurality of sub pixels SPX which is an outer portion of the sub pixel SPX may be larger than a thickness of another part of the second planarization layer 145b which encloses side surfaces of the first connection electrode CE1 and the second connection electrode CE2. A thickness of a part of the second planarization layer 145b disposed in a non-overlapping area of the light emitting diode 150 may be larger than a thickness of another part of the second planarization layer 145b disposed in an area which overlaps the light emitting diode 150. The part of the second planarization layer 145b having a relatively larger thickness may be disposed so as to enclose a surrounding area of the light emitting diode 150.

A thickness of a part of the second planarization layer 145b disposed in the vicinity of the light emitting diode 150 is formed to be large to guide the solvent toward a repair electrode RP in the repair process. Further, a thickness of a part of the second planarization layer 145b disposed in the vicinity of the light emitting diode 150 is formed to be large to suppress the iodine solution from flowing to another area in which the light emitting diode 150 is not disposed, in the repair process. A part of the second planarization layer 145b having a relatively larger thickness is disposed in an outer peripheral part of the plurality of sub pixels SPX and a boundary between the plurality of sub pixels SPX to control the iodine solution so as not to be directed to another conductive layer. Accordingly, the thickness of the second planarization layer 145b disposed on an outer peripheral part of the sub pixel SPX is formed to be large to protect another conductive layer which is not related to the repair process from the iodine solution. Further, an application range of the iodine solution may be controlled so that the iodine solution affects only the repair electrode RP and the conductive adhesive layer AD below the light emitting diode 150.

Next, the repair electrode RP is disposed above each of the first connection electrode CE1 and the second connection electrode CE2. When a defective light emitting diode 150 is removed in the repair process, a repair electrode RP may be disposed to remove the conductive adhesive layer AD. The repair electrode RP may be easily separated from the first connection electrode CE1 and the second connection electrode CE2 by a solvent, during the repair process. Accordingly, during the repair process, the repair electrode RP is separated from the first connection electrode CE1 and the second connection electrode CE2 to easily remove the defective light emitting diode 150.

Referring to FIGS. 3 to 4I, the repair electrode RP includes one or more metal patterns MP and one or more iodine patterns IP.

The metal pattern MP is a metal layer which electrically connects the first connection electrode CE1 and the second connection electrode CE2 below the repair electrode RP and a first bump electrode 156 and a second bump electrode 157 on the repair electrode RP, respectively. The first connection electrode CE1 and the first bump electrode 156 are electrically connected through the metal pattern MP, and the second connection electrode CE2 and the second bump electrode 157 may be electrically connected. The metal pattern MP may be formed of a metal material which reacts with the iodine solution to be removed. For example, the metal pattern MP may be formed of any one of non-ferrous group metals such as silver (Ag), aluminum (Al), nickel (Ni), copper (Cu), zinc (Zn), tin (Sn), or an alloy thereof, or iron group metals such as manganese (Mn), chromium (Cr) and tungsten (W), or an alloy thereof, but is not limited thereto.

An iodine pattern IP is a layer for removing the metal pattern MP during a repair process. The iodine pattern IP is dissolved in a solvent which is applied during the repair process to form an iodine solution. The iodine solution formed from the iodine pattern IP dissolves the metal pattern MP to remove the metal pattern MP. The iodine pattern IP may include an iodine component. For example, the iodine pattern IP may be formed of a solid iodine solid 12 or an iodine compound. For example, if the iodine pattern IP is an iodide compound, the iodine pattern may be formed of any one of silver iodide (AgI), bismuth iodide (Bi2I), silver bismuth iodide ((SBI), AgxBiyIx+3y), cobalt iodide (CoI2), gold iodide (AuI), platinum iodide (PtI2), potassium iodide (KI), and magnesium iodide (MgI2), but is not limited thereto.

In the meantime, in order to allow the solvent applied during the repair process to react with the iodine pattern IP, a side surface of the iodine pattern IP may be exposed from a side surface of the repair electrode RP. At least a part of the side surface of the repair electrode RP is configured with the iodine pattern IP to form the iodine pattern IP and the metal pattern MP of the repair electrode RP in various forms.

For example, referring to FIGS. 4A to 4D, iodine patterns IP of the repair electrodes RPa, RPb, RPc, and RPd may be formed in a mesh pattern having a plurality of openings. A planar shape of the opening may be formed in various shapes, such as a polygonal shape including a rectangular shape and a rhombus shape or a circular shape. The plurality of metal patterns MP may be disposed in the plurality of openings of the iodine pattern IP. In this case, entire side surfaces of the repair electrodes RPa, RPb, RPc, and RPd are formed of the iodine pattern IP to easily react the solvent applied during the repair process and the iodine pattern IP. Further, the first connection electrode CE1 and the second connection electrode CE2, and the light emitting diode 150 may be electrically connected to each other by the metal pattern MP exposed on top surfaces and bottom surfaces of the repair electrodes RPa, RPb, RPc, and RPd.

As another example, referring to FIGS. 4E to 4G, repair electrodes RPe, RPf, and RPg may be formed of a plurality of iodine patterns IP and a plurality of metal patterns MP which are alternately disposed with each other. The plurality of iodine patterns IP and the plurality of metal patterns MP may be formed in a stripe shape and may be alternately disposed. In this case, side surfaces of the repair electrodes RPe, RPf, and RPg may be formed by side surfaces of the plurality of iodine patterns IP and side surfaces of the plurality of metal patterns MP.

As another example, referring to FIG. 4H, a repair electrode RPh may be formed of a plurality of iodine patterns IP and a plurality of metal patterns MP which are alternately disposed with each other. The plurality of iodine patterns IP and the plurality of metal patterns MP may be formed in a ring shape, and the ring-shaped iodine patterns IP and the ring-shaped metal patterns MP may be alternately disposed. At this time, at least a part of the plurality of ring-shaped iodine patterns IP is enclosed by the metal pattern MP so that the side surface may not be exposed to the outside. The plurality of iodine patterns IP may further include a rod-shaped iodine pattern IP which is disposed across the repair electrode RPh. The plurality of ring-shaped iodine patterns IP may be connected to each other by the rod-shaped iodine pattern IP which is disposed across the repair electrode RPh. Accordingly, the solvent may react with the iodine pattern IP therein which is enclosed by the metal pattern MP, by means of the rod-shaped iodine pattern IP which is disposed across the repair electrode RPh.

As another example, referring to FIG. 41, the metal pattern MP of the repair electrode RPi includes a plurality of grooves which is inwardly recessed from the edge. The iodine pattern IP may be disposed in each of the plurality of grooves. The metal pattern MP may include a plurality of grooves which extend from a side surface of the metal pattern MP to an inner area of the metal pattern MP, and the planar shape of the plurality of grooves may be formed in various shapes. The plurality of iodine patterns IP may be disposed so as to be filled in each of the plurality of grooves of the metal pattern MP. Therefore, a side surface of the repair electrode RPi may be formed by a side surface of the metal pattern MP and side surfaces of the plurality of iodine patterns IP.

Next, referring to FIG. 3 again, a conductive adhesive layer AD is disposed on the plurality of repair electrodes RP. The conductive adhesive layer AD may be disposed between the first bump electrode 156 and the second bump electrode 157 of the light emitting diode 150, and the plurality of repair electrodes RP. The conductive adhesive layer AD may be an adhesive layer in which conductive balls are dispersed in an insulating base member. When heat or pressure is applied to the conductive adhesive layer AD, the conductive balls are electrically connected in a portion applied with heat or pressure to have a conductive property, and an area which is not pressurized may have an insulating property. Accordingly, the light emitting diode 150 is disposed on the conductive adhesive layer AD, and heat or pressure is applied to the conductive adhesive layer AD to electrically connect the light emitting diode 150 to the plurality of repair electrodes RP.

The light emitting diode 150 is disposed on the conductive adhesive layer AD. The light emitting diode 150 is an element which emits light by a current, and may be a light emitting diode (LED) or a micro LED, but is not limited thereto. The light emitting diode 150 includes a first semiconductor layer 151, an emission layer 152, a second semiconductor layer 153, a first electrode 154, a second electrode 155, a first bump electrode 156, a second bump electrode 157, and an encapsulation film 158.

The second semiconductor layer 153 is disposed on the conductive adhesive layer AD and the first semiconductor layer 151 is disposed on the second semiconductor layer 153. The first semiconductor layer 151 and the second semiconductor layer 153 may be semiconductor layers doped with n-type and p-type impurities. For example, the first semiconductor layer 151 and the second semiconductor layer 153 may be layers doped with n-type and p-type impurities into a material such as gallium nitride (GaN), indium aluminum phosphide (InAlP), or gallium arsenide (GaAs). The p-type impurity may be magnesium (Mg), zinc (Zn), beryllium (Be), and the like, and the n-type impurity may be silicon (Si), germanium (Ge), tin (Sn), and the like, but are not limited thereto.

The emission layer 152 is disposed between the first semiconductor layer 151 and the second semiconductor layer 153. The emission layer 152 is supplied with holes and electrons from the first semiconductor layer 151 and the second semiconductor layer 153 to emit light. The emission layer 152 may be formed by a single layer or a multi-quantum well (MQW) structure, and for example, may be formed of indium gallium nitride (InGaN) or gallium nitride (GaN), but is not limited thereto.

A part of the first semiconductor layer 151 may protrude from the second semiconductor layer 153 and the emission layer 152. The first electrode 154 is disposed on a bottom surface of a protruding part of the first semiconductor layer 151. The first electrode 154 is an electrode which electrically connects the first semiconductor layer 151 and the driving transistor DT. The first electrode 154 may be electrically connected to any one of the source electrode SE or the drain electrode DE of the driving transistor DT through the conductive adhesive layer AD, the repair electrode RP, and the first connection electrode CE1. Further, in order to compensate for a step between a bottom surface of the first semiconductor layer 151 and a bottom surface of the second semiconductor layer 153, the first electrode 154 may be formed to be thicker than the second electrode 155. Therefore, bottom surfaces of the first electrode 154 and the second electrode 155 may be formed on the same plane. Further, the first electrode 154 may be formed of a material having a low contact resistance with the first semiconductor layer 151 so that charges may easily move from the first electrode 154 to the first semiconductor layer 151. The first electrode 154 may also be referred to as a first ohmic contact electrode. For example, the first electrode 154 may be formed of a conductive material, such as chrome (Cr) or nickel (Ni) and may be formed by a single layer or a double layer of the conductive material, but is not limited thereto.

The second electrode 155 is disposed on the bottom surface of the second semiconductor layer 153. The second electrode 155 is an electrode which electrically connects the second semiconductor layer 153 and the power line. The second electrode 155 may receive a power voltage through the conductive adhesive layer AD, the repair electrode RP, and the second connection electrode CE2. The second electrode 155 may be formed of a material having a low contact resistance with the second semiconductor layer 153 so that charges may easily move from the second electrode 155 to the second semiconductor layer 153. The second electrode 155 may also be referred to as a second ohmic contact electrode. For example, the second electrode 155 may be formed of a conductive material, such as chrome (Cr) or nickel (Ni) and may be formed by a single layer or a double layer of the conductive material, but is not limited thereto.

An encapsulation film 158 which encloses the first semiconductor layer 151, the emission layer 152, the second semiconductor layer 153, the first electrode 154, and the second electrode 155 is disposed. The encapsulation film 158 is formed of an insulating material to protect the first semiconductor layer 151, the emission layer 152, and the second semiconductor layer 153. At least a part of the first electrode 154 and the second electrode 155 is exposed from the encapsulation film 158 so that the first electrode 154 and the second electrode 155 may be electrically connected to the first bump electrode 156 and the second bump electrode 157. For example, the encapsulation film 158 may be formed of an insulating material, such as silicon nitride SiNx or silicon oxide SiOx, but is not limited thereto.

The first bump electrode 156 is disposed between the first electrode 154 and the conductive adhesive layer AD and the second bump electrode 157 is disposed between the second electrode 155 and the conductive adhesive layer AD. The first bump electrode 156 and the second bump electrode 157 are electrodes for bonding the first electrode 154 and the second electrode 155 of the light emitting diode 150 onto the conductive adhesive layer AD. The light emitting diode 150 may be bonded onto the first connection electrode CE1 and the second connection electrode CE2 through the first bump electrode 156 and the second bump electrode 157. For example, the first bump electrode 156 and the second bump electrode 157 may be formed of gold (Au) or a solder, but are not limited thereto.

Next, a bank 146 is disposed on the second planarization layer 145b. The bank 146 is disposed at the boundary between the plurality of sub pixels SPX to suppress the color mixture of light from each of the plurality of sub pixels SPX. The bank 146 may be disposed on a part of the second planarization layer 145b which is disposed on an outer peripheral part of the sub pixel SPX and has a larger thickness. The bank 146 may serve as a dam together with a part of the second planarization layer 145b to suppress the solution in the repair process from flowing elsewhere. For example, the bank 146 may include an organic insulating material, such as benzocyclobutene (BCB)-based resin, acrylic resin, or polyimide, but is not limited thereto.

Next, the plurality of connection lines 130 is disposed on the plurality of line patterns. The plurality of connection lines 130 refers to wiring lines which electrically connect the pads on the plurality of first plate patterns 121 and the pads on the plurality of second plate patterns 123. The plurality of connection lines 130 is disposed on the plurality of first line patterns 122 and the plurality of second line patterns 124. The plurality of connection lines 130 may extend onto the plurality of first plate patterns 121 to be electrically connected to the plurality of pads on the plurality of first plate patterns 121. The plurality of first line patterns 122 is not disposed in an area where the plurality of connection lines 130 is not disposed, among areas between the plurality of first plate patterns 121. Further, even though it is not illustrated in the drawing, the plurality of connection lines 130 is disposed on the plurality of second line patterns 124 to be electrically connected to pads on the plurality of second plate patterns 123 and pads on the plurality of first plate patterns 121.

The plurality of connection lines 130 includes a first connection line 131 and a second connection line 132. The first connection line 131 and the second connection line 132 are disposed between the plurality of first plate patterns 121, between the plurality of second plate patterns 123, and between the plurality of first plate patterns 121 and the plurality of second plate patterns 123. Specifically, the first connection line 131 refers to a wiring line extending in the first direction D1 between the plurality of first plate patterns 121, between the plurality of second plate patterns 123, and between the plurality of first plate patterns 121 and the plurality of second plate patterns 123, among the connection lines 130. The second connection line 132 refers to a wiring line extending in the second direction D2 between the plurality of first plate patterns 121, between the plurality of second plate patterns 123, and between the plurality of first plate patterns 121 and the plurality of second plate patterns 123. Here, the first direction D1 and the second direction D2 may also be referred to as a row direction and a column direction, respectively.

The plurality of connection lines 130 may be formed of a conductive material. For example, the plurality of connection lines 130 may be formed of a metal material such as copper (Cu), aluminum (Al), titanium (Ti), and molybdenum (Mo) or a stacked structure of metal materials such as copper/molybdenum-titanium (Cu/Moti) or titanium/aluminum/titanium (Ti/Al/Ti), but is not limited thereto.

In the case of a general display device, various wiring lines such as a plurality of scan lines and a plurality of data lines extend between the plurality of sub pixels in a straight line shape, and the plurality of sub pixels are connected to one signal line. Therefore, in the general display device, various wiring lines, such as a scan line, a data line, a high potential voltage line, and a reference voltage line, extend from one side to the other side of the display device without being disconnected on the substrate.

In contrast, in the display device 100 according to the exemplary embodiment of the present disclosure, various wiring lines, such as a scan line, a data line, a high potential voltage line, a reference voltage line, and an initialization voltage line having a straight line shape which are considered to be used for the general display device 100, are disposed only on the plurality of first plate patterns 121 and the plurality of second plate patterns 123. That is, in the display device 100 according to the exemplary embodiment of the present disclosure, a wiring line having a straight line shape may be disposed only on the plurality of first plate patterns 121 and the plurality of second plate patterns 123.

In the display device 100 according to the exemplary embodiment of the present disclosure, the pads on two adjacent first plate patterns 121 may be connected by the connection lines 130. Accordingly, the connection line 130 electrically connects the pads on two adjacent first plate patterns 121. Accordingly, the display device 100 according to the exemplary embodiment of the present disclosure may include a plurality of connection lines 130 so as to electrically connect various wiring lines, such as a scan line, a data line, a high potential voltage line, and a reference voltage line, between the plurality of first plate patterns 121.

A plurality of first connection lines 131 of the active area AA may connect the pads on two first plate patterns 121 which are disposed side by side, among the pads on the plurality of first plate patterns 121 disposed to be adjacent in the first direction D1. For example, the scan line may be disposed on the plurality of first plate patterns 121 disposed to be adjacent to each other in the first direction D1 and the pads may be disposed on both ends of the scan line. At this time, the plurality of pads on the plurality of first plate patterns 121 disposed to be adjacent to each other in the first direction D1 may be connected to each other by the first connection line 131 which serves as a scan line. Therefore, the scan line disposed on the plurality of first plate patterns 121 and the first connection line 131 disposed on the first line pattern 122 may serve as one scan line. Further, wiring lines which extend in the first direction D1, among all various wiring lines which may be included in the display device 100, such as an emission signal line, a low potential voltage line, and a high potential voltage line, may also be electrically connected by the first connection line 131, as described above.

A plurality of second connection lines 132 may connect the pads on two first plate patterns 121 which are disposed side by side, among the plurality of first plate patterns 121 disposed to be adjacent in the second direction D2. An internal line on the plurality of first plate patterns 121 disposed in the second direction D2 may be connected by the plurality of second connection lines 132 serving as a data line and may transmit one data voltage. However, the plurality of second connection lines 132 may serve as data lines, high potential voltage lines, low potential voltage lines, or reference lines, but is not limited thereto.

Referring to FIG. 3, end portions of the plurality of connection lines 130 may be connected to the pads on the first plate patterns 121. For example, the fourth conductive layer CL4 which serves as a pad is disposed on the third interlayer insulating layer 143c of the first plate pattern 121. Any one of the plurality of connection lines 130 extends from the first line pattern 122 to side surfaces of the plurality of insulating layers on the first plate pattern 121 and a top surface of the bank 146 to be electrically connected to the fourth conductive layer CL4. For example, the connection line 130 extending to an upper portion of the first plate pattern 121 may be in contact with side surfaces of the multi-buffer layer 141a, the active buffer layer 141b, the gate insulating layer 142, the first interlayer insulating layer 143a, the second interlayer insulating layer 143b, the first planarization layer 145a, the second planarization layer 145b, and the bank 146 disposed on the first plate pattern 121 and the top surface of the bank 146. The connection line 130 may be electrically connected to the fourth conductive layer CL4 through a contact hole formed in the bank 146, the second planarization layer 145b, the first planarization layer 145a, and the passivation layer 144.

Next, the third planarization layer 145c is disposed on the bank 146. The third planarization layer 145c may be disposed on the bank 146 and a part of the second planarization layer 145b having a larger thickness at an outer peripheral part of the sub pixel SPX. The third planarization layer 145c may serve as a dam which suppresses the iodine solution so as not to flow to the conductive layer, other than the repair electrode RP, together with the bank 146 and the second planarization layer 145b. Further, the third planarization layer 145c is disposed so as to cover the connection line 130 which extends onto the bank 146 to protect the connection line 130 from the iodine solution. The third planarization layer 145c may be configured by a single layer or a plurality of layers and may be formed of an organic material. For example, the third planarization layer 145c may be configured by a single layer or a double layer, and for example, may be formed of photoresist or an acrylic organic material, but is not limited thereto.

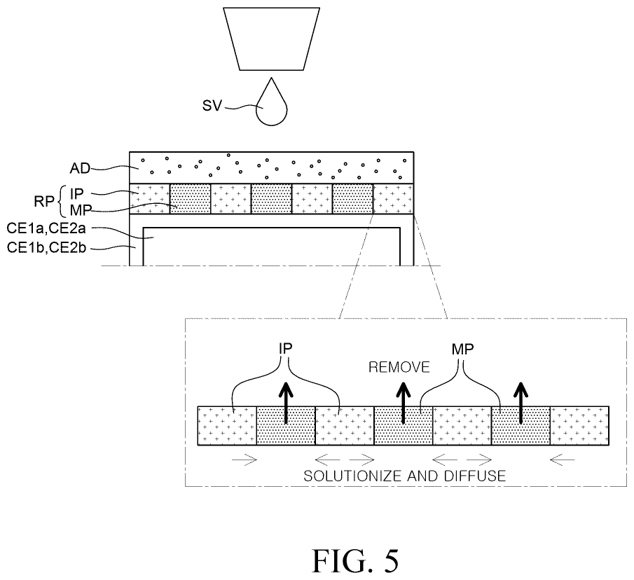

Hereinafter, a repairing method of a sub pixel SPX of the display device 100 according to the exemplary embodiment of the present disclosure will be described with reference to FIGS. 5 to 7.

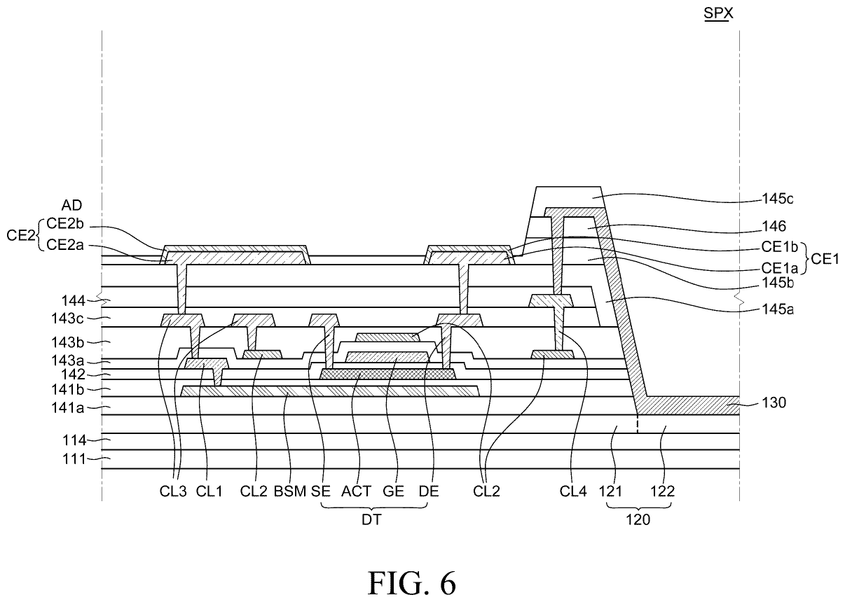

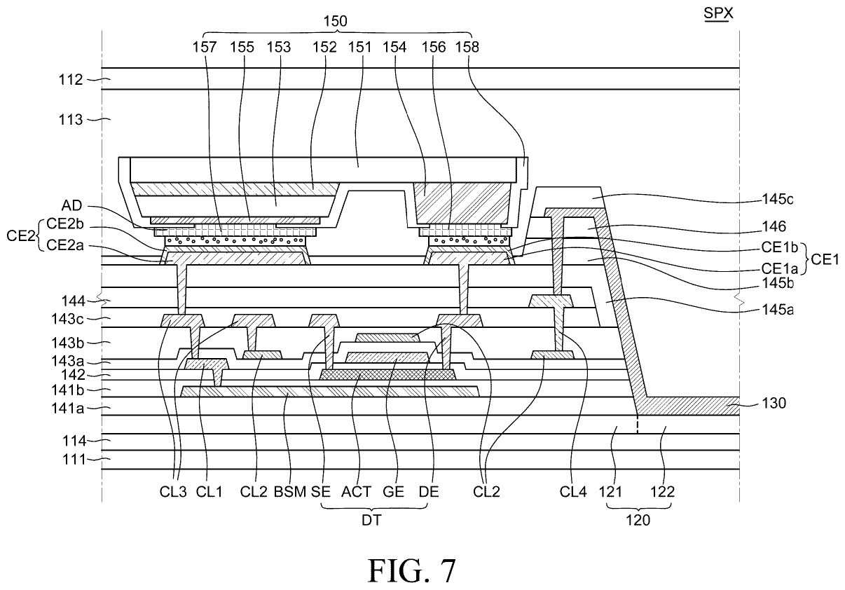

FIGS. 5 to 7 are process diagrams for explaining a repairing method of a display device according to an exemplary embodiment of the present disclosure. Specifically, FIG. 5 is a schematic process diagram for explaining a process of removing a defective light emitting diode 150 using a repair electrode RP. FIG. 6 is a cross-sectional view of a sub pixel SPX after removing the defective light emitting diode 150. FIG. 7 is a cross-sectional view of a sub pixel SPX in which the repair is completed. For the convenience of description, in FIG. 5, only the first connection electrode CE1, the second connection electrode CE2, the repair electrode RP, and the conductive adhesive layer AD are schematically illustrated.

First, when the display device 100 is manufactured, after transferring the light emitting diode 150 on the conductive adhesive layer AD of each of the plurality of sub pixels SPX, a lighting test of the light emitting diode 150 may be conducted. A sub pixel SPX including a defective light emitting diode 150 is detected by the lighting test and the defective sub pixel SPX may be repaired. The defective light emitting diode 150 is removed by the repair process and a new light emitting diode 150 is transferred to repair the defective sub pixel SPX to a normal sub pixel SPX.

Referring to FIG. 5, in order to remove the light emitting diode 150 attached onto the conductive adhesive layer AD, a solvent SV may be applied in an area in which the light emitting diode 150 is disposed. The solvent SV may be formed of a material which dissolves the iodine pattern IP of the repair electrode RP. When the solvent SV is applied on the repair electrode RP including a solid iodine pattern IP, the solvent SV and the iodine pattern IP react with each other to generate the iodine solution. The iodine pattern IP may be solutionized by the solvent SV. For example, the solvent SV may be formed of any one of dimethylformamide (DMF), dimethyl sulfoxide (DMSO), hydriodic acid (HI), acetone, ethyl alcohol, isopropyl alcohol (IPA), but is not limited thereto.

Next, the metal pattern MP is dissolved by the iodine solution to be removed. Iodine included in the iodine solution is one of halogen elements. Iodine has seven peripheral electrons and may form a negative ion with a valence of −1 and the iodine has a property of easily reacting with metals. The iodine solution diffuses to the metal pattern MP which is in contact with the iodine pattern IP to dissolve the metal pattern MP. The metal pattern MP of the repair electrode RP may be removed by halogen reaction with the iodine solution. Therefore, the metal pattern MP of the repair electrode RP may be removed by a chemical method using the iodine solution.

Next, referring to FIGS. 5 and 6 together, during the process in which the iodine pattern IP of the repair electrode RP is solutionized and the metal pattern MP is removed by the iodine solution, the conductive adhesive layer AD and the repair electrode RP may be removed together. As the repair electrode RP which is in contact with the first connection electrode CE1 and the second connection electrode CE2 is removed, the conductive adhesive layer AD and the light emitting diode 150 disposed on the repair electrode RP may also be removed together. As the repair electrode RP disposed between the conductive adhesive layer AD and the first connection electrode CE1 and between the conductive adhesive layer AD and the second connection electrode CE2 is removed, the conductive adhesive layer AD is not fixed to the sub pixel SPX any more. Therefore, the conductive adhesive layer AD and the light emitting diode 150 attached onto the conductive adhesive layer AD may be easily removed.

Accordingly, the solvent SV is applied on the defective sub pixel SPX to remove the defective light emitting diode 150, the conductive adhesive layer AD, and the repair electrode RP. The first connection electrode CE1 and the second connection electrode CE2 are not removed by the iodine solution, but may remain in the sub pixel SPX. The first clad layer CE1b of the first connection electrode CE1 and the second clad layer CE2b of the second connection electrode CE2 are formed of a transparent conductive material which does not react with the iodine solution to protect the first metal layer CE1a and the second metal layer CE2a from the iodine solution so as not to be damaged. Accordingly, in the sub pixel SPX in which a part of the repair process has been performed, as illustrated in FIG. 6, only the first connection electrode CE1 and the second connection electrode CE2 remain, and the repair electrode RP, the conductive adhesive layer AD, and the light emitting diode 150 on the first connection electrode CE1 and the second connection electrode CE2 are removed.

Next, referring to FIG. 7, after removing the defective light emitting diode 150, a new light emitting diode 150 is transferred onto the first connection electrode CE1 and the second connection electrode CE2 to repair the defective sub pixel SPX into the normal sub pixel SPX. Specifically, the conductive adhesive layer AD may be formed above each of the first connection electrode CE1 and the second connection electrode CE2. The light emitting diode 150 is transferred onto the conductive adhesive layer AD and heat or a pressure is applied thereto to electrically connect the light emitting diode 150, and the first connection electrode CE1 and the second connection electrode CE2. Therefore, the defective light emitting diode 150 is removed and a new light emitting diode 150 is transferred to repair the sub pixel SPX.

In a sub pixel SPX in which the repair process has been performed, the repair electrode RP may not be disposed, and in a sub pixel SPX in which the repair process has not been performed, the repair electrode RP may be disposed. Therefore, it is determined whether the sub pixel SPX is repaired by presence of the repair electrode RP.

Next, a filling layer 113 may be formed on the entire lower substrate 111. The filling layer 113 may be formed to cover an upper portion of the first plate pattern 121 in which the light emitting diode 150 is disposed and an area between the plurality of first plate patterns 121 in which the plurality of connection lines 130 is disposed. Finally, the upper substrate 112 is formed on the entire lower substrate 111 on the filling layer 113 to complete the manufacturing process of the display device 100.

In the meantime, according to the related art, the conductive adhesive layer is directly formed on the first connection electrode and the second connection electrode without a repair electrode and the light emitting diode is transferred onto the conductive adhesive layer. With this structure, in order to remove the light emitting diode fixed onto the first connection electrode and the second connection electrode by the conductive adhesive layer, laser is irradiated onto the conductive adhesive layer. However, during this process, there are problems in that the first connection electrode and the second connection electrode are damaged and it is difficult to remove the defective light emitting diode.

In contrast, in the display device 100 according to the exemplary embodiment of the present disclosure, the defective light emitting diode 150 may be simply separated from the first connection electrode CE1 and the second connection electrode CE2 by a chemical method using the iodine solution. The repair electrode RP may be disposed between the first connection electrode CE1 and the conductive adhesive layer AD and between the second connection electrode CE2 and the conductive adhesive layer AD. The repair electrode RP may include a solid iodine pattern IP and a metal pattern MP for electrical connection. During the repair process, a solvent SV for dissolving the iodine pattern IP is applied on the repair electrode RP to solutionize the iodine pattern IP into the iodine solution. The iodine solution may melt the adjacent metal pattern MP to remove. Accordingly, the iodine pattern IP of the repair electrode RP is solutionized between the first connection electrode CE1 and the conductive adhesive layer AD and between the second connection electrode CE2 and the conductive adhesive layer AD and the metal pattern MP may be removed by the iodine solution to remove the repair electrode RP. Therefore, the conductive adhesive layer AD and the light emitting diode 150 attached onto the repair electrode RP may also be easily removed from the sub pixel SPX. Therefore, the repair electrode RP is removed by a chemical method using the iodine solution to easily separate the conductive adhesive layer AD and the defective light emitting diode 150. Further, there is no need to irradiate laser to remove the conductive adhesive layer AD and the damage of the first connection electrode CE1 and the second connection electrode CE2 due to the laser may be suppressed.

Further, in the display device 100 according to the exemplary embodiment of the present disclosure, a dam structure which encloses around the repair electrode RP and the light emitting diode 150 is formed and the iodine solution is generated only in an area where the iodine pattern IP is disposed. Therefore, the damage of the other configuration due to the iodine solution may be suppressed. Even though the solvent SV is applied in the other area where the repair electrode RP is not disposed, there is no iodine component, such as the iodine pattern IP of the repair electrode RP in the corresponding area. Therefore, the iodine solution is not generated and the damage of the wiring line or the electrode which is formed of a metal material may be suppressed. Further, the iodine pattern IP of the repair electrode RP meets the solvent SV to generate the iodine solution so that the iodine solution may be present only in and around the repair electrode RP. Further, a part of the second planarization layer 145b which encloses around the repair electrode RP and the light emitting diode 150, the bank 146, and the third planarization layer 145c serve as a dam to suppress the iodine solution from flowing to a wrong place. Accordingly, the damage of the other wiring line or the electrode, excluding the repair electrode RP, due to the iodine solution is suppressed to improve the yield and the reliability of the display device 100.

The exemplary embodiments of the present disclosure can also be described as follows:

According to an aspect of the present disclosure, a display device includes a lower substrate which includes a plurality of rigid areas disposed to be spaced apart from each other and a malleable area enclosing the plurality of rigid areas; a plurality of first plate patterns disposed in the plurality of rigid areas of the lower substrate; and a plurality of sub pixels which are disposed on the plurality of first plate patterns and each include a connection electrode, a conductive adhesive layer on the connection electrode, and a light emitting diode on the conductive adhesive layer, wherein some of the plurality of sub pixels include a repair electrode which is disposed between the connection electrode and the conductive adhesive layer and is formed of an iodine pattern including an iodine component and a metal pattern.

The iodine pattern may be formed of any one of an iodine solid or an iodine compound.

The metal pattern may be formed of a metal material which is soluble by an iodine solution.

The connection electrode and the conductive adhesive layer may be electrically connected by the metal pattern.

At least a part of a side surface of the repair electrode may be formed of the iodine pattern.

The iodine pattern may be formed by a mesh pattern including a plurality of openings, and the metal pattern may be disposed in each of the plurality of openings.

The iodine pattern and the metal pattern may be formed in a stripe shape, and one repair electrode may be formed of a plurality of iodine patterns and a plurality of metal patterns which are alternately disposed.

The iodine pattern and the metal pattern may be formed in a ring shape, and the one repair electrode may be formed of the plurality of iodine patterns and the plurality of metal patterns which are alternately disposed.

The iodine pattern may further include a rod-shaped iodine pattern disposed across the repair electrode, and the plurality of ring-shaped iodine patterns may be connected to each other by the rod-shaped iodine pattern.

The metal pattern may include a plurality of grooves which are inwardly recessed from an edge of the repair electrode, and the iodine pattern may be disposed in each of the plurality of grooves.

The connection electrode may include a metal layer and a clad layer which covers a top surface and a side surface of the metal layer, and the clad layer may be formed of a transparent conductive material.

The display device may further include a first planarization layer disposed below the connection electrode; a second planarization layer which is disposed on the first planarization layer and the connection electrode and encloses a side surface of the connection electrode; a bank which is disposed on the second planarization layer; and a third planarization layer disposed on the bank. A thickness of a part of the second planarization layer disposed around the light emitting diode may be larger than a thickness of the other part of the second planarization layer which overlaps the light emitting diode, and the bank and the third planarization layer may be disposed on the part of the second planarization layer.

The part of the second planarization layer, the bank, and the third planarization layer may overlap an outer peripheral part of the plurality of sub pixels and a boundary between the plurality of sub pixels.

In some sub pixels among the plurality of sub pixels, the conductive adhesive layer may be electrically connected to the connection electrode by means of the repair electrode, and in the other sub pixels among the plurality of sub pixels, the conductive adhesive layer may be in contact with a top surface of the connection electrode to electrically connect the conductive adhesive layer to the connection electrode.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a lower substrate which includes a plurality of rigid areas spaced apart from each other and a malleable area enclosing the plurality of rigid areas;
a plurality of first plate patterns disposed in the plurality of rigid areas of the lower substrate; and
a plurality of sub pixels disposed on the plurality of first plate patterns and each including a connection electrode, a conductive adhesive layer on the connection electrode, and a light emitting diode on the conductive adhesive layer,
wherein some of the plurality of sub pixels include a repair electrode disposed between the connection electrode and the conductive adhesive layer, the repair electrode including an iodine pattern and a metal pattern, the iodine pattern including an iodine component and a metal pattern.

2. The display device according to claim 1, wherein the iodine pattern includes one of an iodine solid or an iodine compound.

3. The display device according to claim 1, wherein the metal pattern includes a metal material that is soluble by an iodine solution.

4. The display device according to claim 1, wherein the connection electrode and the conductive adhesive layer are electrically connected by the metal pattern.

5. The display device according to claim 1, wherein at least a part of a side surface of the repair electrode is formed of the iodine pattern.

6. The display device according to claim 1, wherein the iodine pattern includes a mesh pattern including a plurality of openings, and the metal pattern is disposed in each of the plurality of openings.

7. The display device according to claim 1, wherein the iodine pattern and the metal pattern each includes a stripe shape, and one repair electrode includes a plurality of iodine patterns and a plurality of metal patterns which are alternately disposed.

8. The display device according to claim 1, wherein the iodine pattern and the metal pattern each includes a ring shape, and one repair electrode includes a plurality of iodine patterns and a plurality of metal patterns which are alternately disposed.

9. The display device according to claim 8, wherein the iodine pattern further includes a rod-shaped iodine pattern disposed across the repair electrode, and the plurality of ring-shaped iodine patterns are connected to each other by the rod-shaped iodine pattern.

10. The display device according to claim 1, wherein the metal pattern includes a plurality of grooves which are inwardly recessed from an edge of the repair electrode, and the iodine pattern is disposed in each of the plurality of grooves.

11. The display device according to claim 1, wherein the connection electrode includes:
a metal layer; and
a clad layer which covers a top surface and a side surface of the metal layer, and
wherein the clad layer is formed of a transparent conductive material.

12. The display device according to claim 1, further comprising:
a first planarization layer disposed below the connection electrode;
a second planarization layer disposed on the first planarization layer and the connection electrode, the second planarization layer enclosing a side surface of the connection electrode;
a bank disposed on the second planarization layer; and
a third planarization layer disposed on the bank,
wherein a thickness of a first part of the second planarization layer disposed around the light emitting diode is larger than a thickness of a second part of the second planarization layer which overlaps the light emitting diode, and the bank and the third planarization layer are disposed on the part of the second planarization layer.

13. The display device according to claim 12, wherein the first part of the second planarization layer, the bank, and the third planarization layer overlap an outer peripheral part of the plurality of sub pixels and a boundary between the plurality of sub pixels.

14. The display device according to claim 1, wherein in first sub pixels among the plurality of sub pixels, the conductive adhesive layer is electrically connected to the connection electrode by means of the repair electrode, and in second sub pixels among the plurality of sub pixels, the conductive adhesive layer is in contact with a top surface of the connection electrode and electrically connects the conductive adhesive layer to the connection electrode.

15. The display device according to claim 3, wherein the iodine solution is formed by the iodine pattern being dissolved in a solvent, and
wherein the iodine pattern and the metal pattern can be dissolved by the solvent applied in a repair process.

16. The display device according to claim 11, wherein the clad layer is formed of a material which does not react with an iodine solution.
